(19) United States
(12) Patent Application Publication
(10) Pub. No.: US 2009/0115051 A1
(43) Pub. Date: May 7, 2009

(54) Electronic Circuit Package

(76) Inventors: Lap-Wai Lydia Leung, Hong Kong (CN); Yu-Chih Chen, Hong Kong (CN); Chi Kuen Leung, Hong Kong (CN); Jyh-Rong Lin, Tucheng City (TW); Chang Hwa Chung, Hong Kong (CN)

Correspondence Address: WELLS ST. JOHN P.S., 601 W. FIRST AVENUE, SUITE 1300, SPOKANE, WA, 99201, US

(21) Appl. No.: 11/934,007

(22) Filed: Nov. 1, 2007

(51) Int. Cl. H01L 23/12

(52) U.S. Cl. 257/701; 257/E23.003

(57) ABSTRACT

An electronic circuit package has a thin-film circuit integrated with the ceramic substrate. The thin-film circuit includes at least two passive circuit elements joined by an integrated electrical interconnect. At least one active power electronic component mounted on the ceramic substrate and is electrically connected with the integrated thin-film circuit.

### BACKGROUND TO THE INVENTION

1. Field of the Invention

The current invention relates to an electronic circuit package and in particular to a ceramic substrate for holding both passive and active electronic circuit components.

2. Background Information

Modern electronic devices are characterised by small size and large functionality. Consumers desire products with more and more functions, but without compromising on size and weight. Such devices are also characterised by wireless interconnectivity for communicating, sharing or downloading information. In response, electronic designers are continually striving to make smaller more efficient electronic circuit packages. However, various design considerations such as track/interconnect routing, parasitics, losses and heating affect the size and form-factor of electronic packages, particularly in radio frequency applications. Another aspect that affects size and form-factor is the number of passive circuit component in modern electronic circuitry. Modern electronic circuits contain a large number of semiconductor integrated circuit (IC) devices, however it is estimated there between 60-70% of components in modern electronic circuits are discrete passive components. Although modern techniques such as Low Temperature Co-fired Ceramic (LTCC) and thin-film are used to reduce the size of passive components separation between active and passive devices is still governed by assembly capabilities and many active devices are not closely placed to associated passive components in order to optimise module layout. Form-factor is also governed by assembly capabilities and minimum separation between IC dies.

U.S. Pat. No. 6,545,225 discloses a small form-factor electronic circuit package in which passive components, such as capacitors, resistors and inductors, are formed on a substrate of an insulating material using a thin film technique. A planarizing layer of glass is first coated onto the insulating material and then the thin film circuits are formed on the barrier layer. The partial or full integration of passive components onto the substrate leads to the creation of a module which is very compact.

Another small form-factor electronic circuit package is disclosed in Taiwanese patent publication TW0494560B. In this package a patterned insulation layer is located on the upper surface of a ceramic substrate and a thin film passive device layer is locating on the patterned insulation layer. A passivation layer is formed on the thin film passive device layer and a chip is located on the passivation layer and electrically connected with the passive device through a multi-level interconnect.

The packages disclosed in these two patents have insulating or barrier layers on the supporting substrate to achieve passive components with acceptable performance at RF operating frequencies. However, the insulating and barrier layers deteriorate the thermal spreading performance of the package and so these packages are not suitable for high power application.

Thus there exists a need for an improved electronic circuit package that overcomes or ameliorates at least some of the disadvantages with the prior art or at least provides the public with a useful alternative.

### SUMMARY OF THE INVENTION

Accordingly there is disclosed herein an electronic circuit package comprising a ceramic substrate, a thin-film circuit integrated with the ceramic substrate and having at least two passive circuit elements joined by an integrated electrical interconnect, and at least one active power electronic component mounted on the ceramic substrate and electrically connected with the integrated thin-film circuit.

Preferably, the thin-film circuit is integrated with the ceramic substrate by a method selected from a group comprising metal and dielectric deposition, electroplating and etching.

Preferably, the active electronic component is mounted to the ceramic substrate without any dielectric material between the active electronic component and the ceramic substrate.

Preferably, the active electronic component is mounted on the die bond pad with adhesive which could be conductive or non-conductive.

Preferably, the thin-film circuit is integrated with the ceramic substrate.

Preferably, the passive circuit elements are selected from the group consisting of a resistor, a capacitor, an inductor, a through hole, a via and a wrap-around.

Preferably, the thin-film circuit is selected from a group consisting of an LC matching network, a low-pass filter, a band-pass filter, a high-pass filter, a diplexer and a balun.

Preferably, the active electronic component comprises a semiconductor chip device or packaged IC.

Preferably, the semiconductor chip device is selected from a group consisting of a RF die, a low-noise amplifier, a power amplifier and a switch.

Preferably, the electronic circuit package comprises a ceramic substrate, a thin-film circuit integrated with the ceramic substrate, thin-film circuit comprising at least two passive circuit elements connected to a bond pad and wherein there is no dielectric layer between the die bond pad and the substrate, and an active electronic component mounted to the die bond pad using a conductive or non conductive adhesive.

### BRIEF DESCRIPTION OF THE DRAWINGS

FIG. 1 is a schematic overview of an electronic circuit package according to the invention,

FIG. 2 is a side schematic view of the package, and

FIG. 3 is an enlarged size schematic view of area A of FIG. 2.

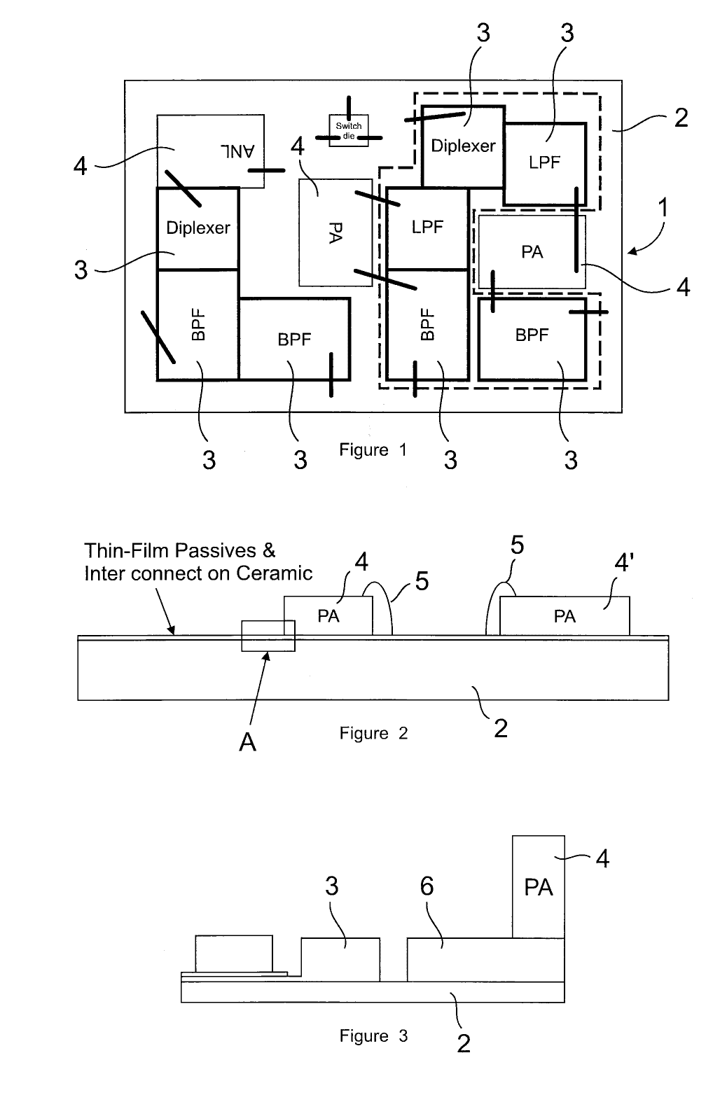

### DETAILED DESCRIPTION OF THE EXEMPLARY EMBODIMENTS

Referring to the drawings, in an exemplified embodiment of the invention there is an electronic circuit package 1 comprising a ceramic supporting substrate 2, a plurality of thin-film circuits 3 deposited on the ceramic substrate 2 and a plurality of active electronic devices 4. The thin-film circuits 3 comprise a plurality of passive circuit elements which in combination with the active electronic devices 4 form a functioning electronic circuit.

The passive circuit elements of the thin-film circuits 3 may include, but are not limited to, any one of resistors, capacitors, inductors, through-holes, vias and/or edge wrap-arounds. These components are formed on the ceramic by depositing thin films of metal, dielectric or photoresist materials using plasma enhanced chemical vapor deposition (PECVD), physical vapor deposition (PVD) such as sputtering, patterning and etching and electroplating processes. The formation of thin film circuit using some of the aforementioned methods has been practiced for over 30 years and is well within the capability of those skilled in the art. The electroplating process is used to control the metal thickness of components whose performance is sensitive to metal thickness, for example, Q-factor of inductors and insertion loss of transmission line. The thin film passive circuit elements are joined to form thin-film electronic circuits by interconnects also integrated with the ceramic substrate 2. The passive components may be of any arbitrary shape, taking account of the voltage, current, frequency characteristics of the electrical signal and the shape and size of the active electronic components they will carry, and are arranged to form passive circuit elements such as LC matching networks, low-pass filters, band-pass filers, high-pass filters, diplexers and the like.

Die Bond pads 6 are also formed on the substrate for mounting the active components 4. The die bond pads are formed by electroplating or one of the thin-film techniques described above directly onto the substrate without an intervening dielectric layer between the pad 6 and ceramic substrate 2.

The active electronic components 4 of the package may include, but are not limited to, semiconductor devices and dies such as transistors, low noise amplifiers (LNAs), power amplifiers, switches and the like. In the preferred embodiment the package includes at least one power active device, such as a power amplifier, together with other active devices, for example LNAs and switches. The active devices can be bare dies or packaged integrated circuits (ICs). Each active component is mounted to the ceramic substrate 2 in an area over or directly adjacent to the metal layer 3 formed on the ceramic substrate 2. The active components are attached to the die bond pads 6 via conductive adhesive or via non-conductive adhesive and bonding wires 5. There is no intervening insulating material such as oxide between the active component 4 and the substrate 2. The active components 4 are mounted as closely as possible to the associated passive elements and circuit 3 integrated with this ceramic.

A circuit package of the current invention is particularly useful in radio frequency (RF) front end modules. A typical RF front end comprises everything from the antenna to the intermediate frequency (IF) stage of an RF receiver, and may include a low noise amplifier (LNA), one or more mixer stages, a phase lock loop (PLL), automatic gain control (AGC) and filters. It includes both active and passive analog components operating at high frequency. The active components can be mounted on a ceramic support substrate and interconnected with thin-film passive components integrated with the ceramic substrate. Such a construction provides a simpler assembly procedure and lower assembly capabilities, for example minimum separation between dies, minimum separation between die and discrete integrated passive devices, without affecting the performance of the module, for example, minimum bond wire length. Integrating thin-film passive components with the ceramic substrate improves routing flexibility and reduces the package form-factor. Because active components can be mounted directly above their associated passive components, bond wire lengths are shorter which reduces parasitics and losses especially operating at high frequency. The various passive components are connected by integrated on-ceramic interconnects with well-matched impedance instead of bonded-wires resulting in better impedance control and thus reduced losses. Because the die bond pads of active components such as power dies are formed directly on the ceramic substrate 2 without any intervening dielectric layer the package has better thermal spread effect than prior art assembly methods which typically have an insulating layer, for example, silicon oxide, BCB, between the die and ceramic/glass/silicon substrate. Testing by the inventors reveals that surface temperature can be reduced by up to 15% by removing the insulating layer.

It should be appreciated that modifications and/or alterations obvious to those skilled in the art are not considered as beyond the scope of the present invention.

What is claimed is:

1. An electronic circuit package comprising:
a ceramic substrate,
a thin-film circuit integrated with the ceramic substrate, the thin-film circuit comprising at least two passive circuit elements joined by an electrical interconnect, and
at least one active power electronic component mounted on the ceramic substrate and electrically connected with the integrated thin-film circuit.

2. The package of claim 1 wherein the thin-film circuit is integrated with the ceramic substrate by a method selected from a group comprising metal and dielectric deposition, electroplating and etching.

3. The package of claim 1 wherein the active electronic component is mounted to the ceramic substrate without any dielectric material between the active electronic component and the ceramic substrate.

4. The package of claim 3 wherein active electronic component is mounted on the die bond pad with adhesive which could be conductive or non-conductive.

5. The package of claim 1 wherein the thin-film circuit is integrated with the ceramic substrate.

6. The package of claim 1 wherein the passive circuit elements are selected from the group consisting of a resistor, a capacitor, an inductor, a through hole, a via and a wrap-around.

7. The package of claim 1 wherein the thin-film circuit is selected from a group consisting of an LC matching network, a low-pass filter, a band-pass filter, a high-pass filter, a diplexer and a balun.

8. The package of claim 1 wherein the active electronic component comprises a semiconductor chip device or packaged IC.

9. The package of claim 8 wherein the semiconductor chip device is selected from a group consisting of a RF die, a low-noise amplifier, a power amplifier and a switch.

10. An electronic circuit package comprising:
a ceramic substrate,
a thin-film circuit integrated with the ceramic substrate, thin-film circuit comprising at least two passive circuit elements connected to a bond pad and wherein there is no dielectric layer between the bond pad and the substrate, and
an active electronic component mounted to the bond pad using a conductive or non conductive adhesive.
